(19) United States
(12) Patent Application Publication
(10) Pub. No.: US 2022/0379650 A1
(43) Pub. Date: Dec. 1, 2022

(54) LABEL INCLUDING A LENS OR LENS ARRAY

(71) Applicant: Multi-Color Corporation, Batavia, OH (US)

(72) Inventors: Barron G. McKillip, Cincinnati, OH (US); Alexander Craig Bushman, Loveland, OH (US); Alec M. Kasza, Sylvania, OH (US); Oliver Crowhurst, Schwenksville, PA (US)

(21) Appl. No.: 17/816,147

(22) Filed: Jul. 29, 2022

Related U.S. Application Data
(63) Continuation-in-part of application No. 17/353,067, filed on Jun. 21, 2021.
Application No. 17/353,067 is a continuation of application No. 16/993,833, filed on Aug. 14, 2020.
Application No. 16/993,833 is a division of application No. 16/254,871, filed on Jan. 23, 2019, now abandoned.
(60) Provisional application No. 63/226,984, filed on Jul. 29, 2021.
(60) Provisional application No. 62/620,691, filed on Jan. 23, 2018.

(51) Int. Cl. B42D 25/36; G02B 3/00; G02B 1/10; B41F 19/00; B42D 25/425; B42D 25/45; B41F 19/02; B42D 25/328; G03F 7/00

(52) U.S. Cl. CPC B42D 25/36; G02B 3/0006; G02B 1/10; B41F 19/001; B42D 25/425; B42D 25/45; B41F 19/02; B42D 25/328; G03F 7/0002

(57) ABSTRACT

A label, and methods and systems for preparing the label. The label includes a lens or lens array. The label includes at least one surface, a portion of which is embossed, and a lens array provided by the embossed portion of the at least one surface. The method includes applying a material to a substrate and contacting a surface of the material with a master engraving to provide an embossed region on a least a portion of the surface of the material, wherein the embossed region provides at least one lens.

### CROSS-REFERENCE TO RELATED APPLICATIONS

The present application claims priority to, and benefit of the filing date of, U.S. Provisional Patent Application Ser. No. 63/226,984, filed Jul. 29, 2021, the disclosure of which is hereby incorporated herein by reference in its entirety. The present application also is a continuation-in-part of Ser. No. 17/353,067, filed Jun. 21, 2021 (and published on Oct. 7, 2021 as U.S. Patent Application Publication No. 2021/0309040), the disclosure of which is hereby incorporated by reference in its entirety—which is a continuation application of U.S. patent application Ser. No. 16/993,833, filed Aug. 14, 2020 (and published on Nov. 26, 2020 as U.S. Patent Application Publication No. 2020/0369068), the disclosure of which is hereby incorporated by reference in its entirety—which is a divisional application of U.S. patent application Ser. No. 16/254,871, filed Jan. 23, 2019 (and published on Jul. 25, 2019 as U.S. Patent Application Publication No. 2019/0225004), the disclosure of which is hereby incorporated herein by reference in its entirety—which claims priority to, and benefit of the filing date of, U.S. Provisional Patent Application Ser. No. 62/620,691, filed Jan. 23, 2018, the disclosure of which is hereby incorporated herein by reference in its entirety.

### FIELD OF THE INVENTION

The present invention relates to labels including materials and/or structure that provide optical effects to graphics associated with the label.

### BACKGROUND OF THE INVENTION

This section is intended to introduce the reader to various aspects of art that may be related to various aspects of the present invention, which are described and/or claimed below. This discussion is believed to be helpful in providing the reader with background information to facilitate a better understanding of various aspects of the present invention. Accordingly, it should be understood that these statements are to be read in this light, and not as admissions of prior art.

Presently, certain labels (or other packaging components) may incorporate a lens (or an array of lenses—a lens array) that provides visual effects not readily achievable with conventional printing methods. However, there are several drawbacks to the current versions of those labels.

For example, one current method of incorporating a lens array on a pressure sensitive label or packaging component is to purchase pre-manufactured substrate films, having a lens or lenses therein or thereon (pre-manufactured embossed films) that are reinserted into a printing press to allow for additional graphics to be added. A label formed from this prior art process is shown in FIG. 1. Another current method that relies on the obtaining of a premanufactured substrate film is called CAST AND CURE™, which includes a holographic film (commercially available from Breit Technologies of Overland Park, Kans., United States). In the CAST AND CURE™ process, a master engraving (such as on a cylinder or plate) is used to create a film having a micro-embossed surface (the embossed regions being created by the engraving. Separately, an overprint varnish coating is applied to a different film, and then the CAST AND CURE™ film, including the micro-embossed surface, is laminated over the coating and is cured with UV energy—i.e., the web of film including a micro-embossed surface is used as a cast to impart its micro-embossed pattern onto a surface of the coating to form a lens array, which is then cured. The CAST AND CURE™ film is then removed and discarded. In yet another method, a lens or lens array can be applied or formed to a label substrate utilizing cold foil or hot stamp film during the printing process.

However, each of these current methods requires that a pre-manufactured film be used, thereby increasing the steps of the process and increasing the amount of materials to be used, thereby resulting in a more expensive process. Further, the embossing made in methods, such as the CAST AND CURE™ method, do not provide high quality optical effects for images (or high quality images). This is because the embossed film used to provide the emboss to the CAST AND CURE™ coating is a secondary embossing step. As described, a master engraving is first used to make an embossed film. And that embossed film is then used to make the emboss that is on the coating of the final label (or other embossed material). Thus, the emboss on the final material will not be as sharp as the emboss on the original film (which was provided by the original master engraving). Further, once the final embossed product is prepared, the secondary embossed CAST AND CURE™ film has to be removed and discarded. This adds extra materials and steps to the process, increasing time, complexity, and cost.

Further, processes requiring that a pre-manufactured film with a lens or lenses thereon be reinserted to a printing press requires proper registration in order to ensure that the additional printed graphics appear properly relative to the pre-printed lens or lenses. This adds another step to the process where mis-registration can occur, leading to waste of labels, and further increased cost.

Further still, in processes where the images can be applied to a label substrate utilizing cold foil or hot stamp film during the printing process, there are some drawbacks to cold foil printing and hot stamping processes. For examples, hot stamp foils have a release coat on one side and an adhesive layer on the other which can both fluctuate during the manufacturing process of the hot stamp foil. This results in the potential for poor transfer and bond to the label substrate. Additionally, cold foil has a coating on the film that allows the foil to easily release during the printing process. Post printing on the cold foil after application to the label substrate can be difficult due to the release coating present on the surface of the cold foil image. This remains true with the hot stamp image as well. Additionally, both cold foil and hot stamp images easily fail tape testing and product resistance testing. Further, in many such labels, the image is subject to abrasion.

### SUMMARY OF THE INVENTION

Certain exemplary aspects of the invention are set forth below. It should be understood that these aspects are presented merely to provide the reader with a brief summary of certain forms the invention might take and that these aspects are not intended to limit the scope of the invention. Indeed, the invention may encompass a variety of aspects that may not be explicitly set forth below.

As described above, current methods of incorporating a lens or lens array on a pressure sensitive label or packaging component are expensive, due to the fact the methods require a separate pre-manufactured film be used. There may also be problems with mis-registration of graphics, due to the necessary re-registration of a preprinted substrate, and problems with methods using cold foil printing and hot foil stamping.

Various aspects of the present invention, however, overcome the drawbacks described in the Background by providing labels, methods of producing same, and apparatus for producing same that eliminate the excessive cost of using pre-manufactured (embossed) films, cold foils, and hot stamp foils. The labels (such as those produced via methods and apparatus described herein) include an imprinted lens array created via embossing a surface on the label in order to provide a lens or array of lenses thereon. The imprinted lens or lens array associated with the label may be referred to herein as a micro-structure lens array. And the micro-structure lens array herein may include a multilevel diffractive lens. As used herein, “micro-structure lens array” encompasses forms lens arrays having lenses with dimensions in the nanometer, micrometer, or millimeter ranges. However, it will be recognized by those skilled in the art that the aspects of the invention described herein can be used to provide lens arrays that have dimensions larger or smaller than these ranges.

To those ends, one aspect of the invention provides a label comprising at least a first layer, a portion of which (such as a surface of which) is embossed, and at least one lens, or a lens array (e.g., a micro-structure lens array, such as a lens array that includes a multilevel diffractive lens), provided by the embossed portion of the first layer. In various embodiments, the first layer that is embossed may be a coating, or ink, or varnish, for example. This embossed first layer may be positioned on either side of a film (e.g., a transparent film). Thus, the embossed first layer may be positioned on the side of the film that would be to the outside of the label once the label is associated with an article; alternatively, the embossed first layer may be positioned such that it lies underneath the film (i.e., toward the inside of the label once associated with an article). When the embossed first layer is positioned underneath the film, this can prevent abrasion of the embossed surface.

Another aspect of the invention is to position the embossed first layer (having the leans or lens array therein or thereon) relative to graphics provided by a second layer of the label, in order to create a visual effect, e.g., the appearance of a three-dimensional image (i.e., a three-dimensional appearance of graphics provided on the second layer of the label that is separate from the first layer embossed with the micro-structure lens array). In such a situation, the embossed lens or lens array of the first layer, and the graphics of the second layer can operate in concert with one another (such as by being viewed together) to provide an image that appears three dimensional (or some other optical effect). To accomplish this, the embossed microstructure lens array may be a sculptured lens (or lens array) that is designed to conform to the contours of the graphics to which one intends to give a three-dimensional appearance (or other optical effect). In certain embodiments, the angle of the embossing creates light reflections that give the image the three-dimensional appearance.

Additionally, or alternatively, the label may also include images that are themselves formed via being imprinted (such as via embossing) of the first layer. In certain embodiments, the embossing of the first layer may be done in the shape, contour, etc., of the graphics (such as text, images, etc.) that are desired top appear to an observer of the label. Other embodiments may include embossing of the first layer in the shape, contour, etc., of the graphics (such as text, images, etc.) that are desired to appear to an observer of the label, coupled with the formation of at least one lens or lens array that provides further visual effect to the embossed graphics. Such a lens or lens array may be provided on the first layer, or on a separate layer of the label.

Another aspect of the invention provides a method for preparing a label. The label may include at least one lens, or a lens array (e.g., a micro-structure lens array). In this aspect, the method comprises applying a coating to a film, and embossing a portion of the coating to provide a lens array (e.g., a micro-structure lens array). In alternate embodiments, another surface may have at least a portion thereof embossed.

One embodiment of this aspect of providing a method of preparing a label may include applying a material to a substrate; and contacting a surface of the material with a master engraving to provide an embossed region on a least a portion of the surface of the material; wherein the embossed region provides at least one lens.

Another embodiment of this aspect of providing a method of preparing a label may include contacting a surface of a material with a master engraving to provide an embossed region on a least a portion of the surface of the material; and applying the material including an embossed region to a substrate; wherein the embossed region provides at least one lens.

Another embodiment of this aspect of providing a method of preparing a label may include contacting a surface of a material with a master engraving to provide an embossed region on a least a portion of the surface of the material, as the material is being applied to a substrate; wherein the embossed region provides at least one lens.

Another aspect of the invention provides a system for preparing a label having at least one lens, or a lens array (e.g., a micro-structure lens array). The system may include an embossing apparatus associated with a printing apparatus.

### BRIEF DESCRIPTION OF THE DRAWINGS

The accompanying drawings, which are incorporated in and constitute a part of this specification, illustrate embodiments of the invention and, together with the general description of the invention given above and the detailed description of the embodiments given below, serve to explain the principles of the present invention.

FIG. 1 is a photograph of a pre-manufacture image substrate that was then re-registered in a secondary process to apply printed graphics (i.e., a prior art process).

FIG. 2A is a schematic of a label in accordance with the principles of the present invention.

FIG. 2B shows an example of a first layer (which may be a coating) of a label in accordance with principles of the present invention, including an embossed lens or lens array.

FIG. 2C shows an example of a second layer of a label in accordance with principles of the present invention, including graphics that can be registered to the lens or lens array of the first layer of FIG. 2B.

FIG. 3 shows an example of an apparatus and process for embossing a surface of a component of a label in accordance with various aspects of the present invention.

FIG. 4 shows an example of an apparatus and process for embossing in accordance with various aspects of the present invention, with the apparatus being shown associated with a printing apparatus.

FIG. 5 is a schematic of another embodiment of a label in accordance with principles of the present invention.

FIG. 6 is a schematic of a modified version of the embodiment of the label of FIG. 5, with additional layers added.

FIG. 7 is a schematic of another embodiment of a label in accordance with principles of the present invention.

FIG. 8 is a schematic of another embodiment of a label in accordance with principles of the present invention.

FIG. 9 is a schematic of another embodiment of a label in accordance with principles of the present invention.

FIG. 10 is a schematic of another embodiment of a label in accordance with principles of the present invention.

FIG. 11 is a schematic of another embodiment of a label in accordance with principles of the present invention.

FIG. 12 is a schematic of another embodiment of a label in accordance with principles of the present invention.

FIG. 13 is a schematic of another embodiment of a label in accordance with principles of the present invention.

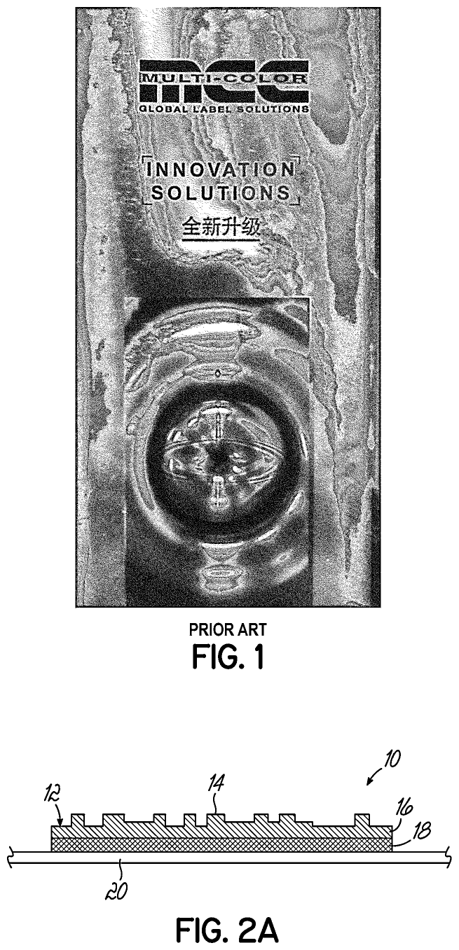

### DETAILED DESCRIPTION

One or more specific embodiments of the present invention will be described below. In an effort to provide a concise description of these embodiments, all features of an actual implementation may not be described in the specification. It should be appreciated that in the development of any such actual implementation, as in any engineering or design project, numerous implementation-specific decisions must be made to achieve the developers' specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

As described above, current methods of incorporating an imprinted lens array on a pressure sensitive label or packaging component are expensive, due to the fact the methods require a separate pre-manufactured film be used. There may also be problems with mis-registration of graphics, due to the necessary re-registration of a preprinted substrate, and problems with methods using cold foil printing and hot foil stamping.

Various aspects of the present invention, however, overcome the drawbacks described in the Background by providing labels, methods of producing same, and apparatus for producing same that eliminate the excessive cost of using pre-manufactured (embossed) films, cold foils, and hot stamp foils. The labels (such as those produced via methods and apparatus described herein) include an imprinted lens or lens array created via embossing a surface on the label in order to provide a lens or array of lenses thereon. The imprinted lens or lens array associated with the label may be referred to herein as a micro-structure lens array. And the micro-structure lens array herein may include a multilevel diffractive lens. As used herein, “micro-structure lens array” encompasses forms lens arrays having lenses with dimensions in the nanometer, micrometer, or millimeter ranges. However, it will be recognized by those skilled in the art that the aspects of the invention described herein can be used to provide lens arrays that have dimensions larger or smaller than these ranges.

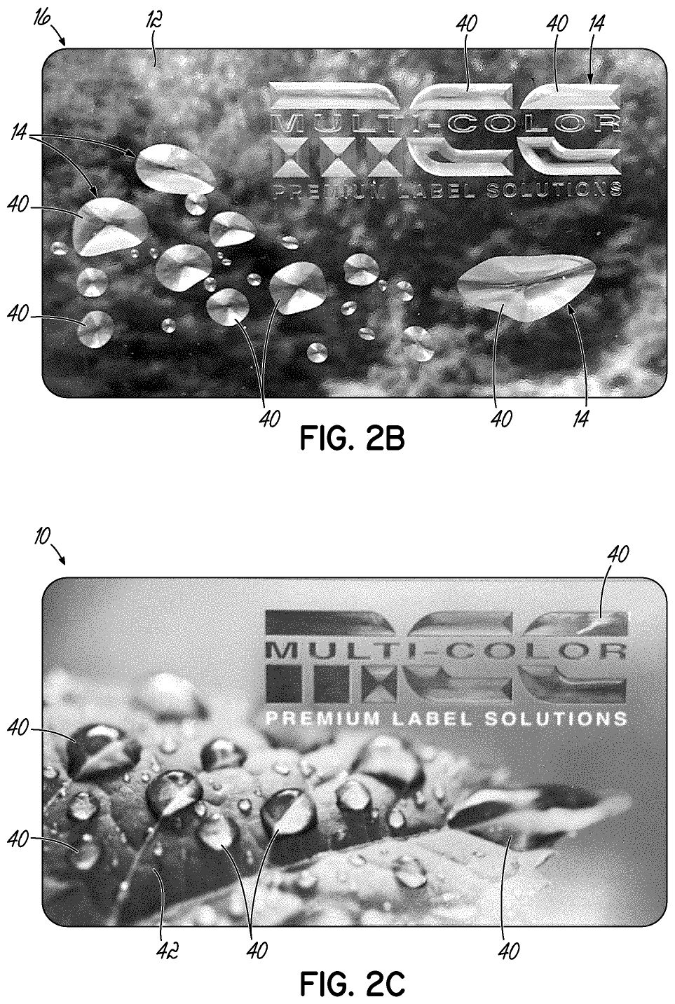

In that regard, and referring now to FIGS. 2A-4, one aspect of the invention provides a label 10 comprising at least a first layer 16, at least a portion 14 of which (such as a surface 12) is embossed, such that at least one lens, or a lens array, is provided by the embossed portion 14 of the at least one surface 12. The at least one lens may be a multilevel diffractive lens, for example, (or the lens array may include multiple multilevel diffractive lenses, for example). The label 10 (such as those produced via methods and apparatus described herein) thus includes an imprinted lens or lens array (e.g., a micro-structure lens array) created via embossing a surface 12 on the label 10 (such as on the surface 12 of the first layer 16 of the label 10) in order to provide visual effects (optical effects) to images of the label. The emboss may be directly created by a master engraving, and particularly by contacting a material to be embossed (i.e., the material of the first layer 16) with the master engraving itself. In various embodiments, the first layer 16 that is embossed may be a coating, or ink, or varnish, for example.

And so, another aspect of the invention (and referring particularly to FIGS. 2B and 2C) involves positioning the embossed first layer 16 (having the lens or lens array 40 therein or thereon) relative to graphics 42 provided by a second layer 18 of the label 10, in order to create a visual effect, e.g., the appearance of a three-dimensional image (i.e., a three-dimensional appearance of graphics 42 provided on the second layer 18 of the label 10 that is separate from the first layer 16 embossed with the micro-structure lens array 40). In such a situation, the embossed lens or lens array 40 of the first layer 16, and the graphics 42 of the second layer 18 can operate in concert with one another (such as by being viewed together) to provide an image that appears three dimensional (or some other optical effect). To accomplish this, the embossed microstructure lens array may be a sculptured lens (or lens array) that is designed to conform to the contours of the graphics to which one intends to give a three-dimensional appearance (or other optical effect). In certain embodiments, the angle of the embossing creates light reflections that give the image the three-dimensional appearance.

As an example, FIG. 2B shows a first layer 16 of a label, the first layer 16 having portions 14 of a surface 12 thereof embossed to imprint a lens or lens array 40 thereon. (As an example, the lenses 40 could be represented by the embossed portions 14 of surface 12 shown in FIG. 2A.) In a particular embodiment, first layer 16 may comprise a coating—such as a coating that includes a varnish. FIG. 2C, then, includes the second layer 18 of the label, that second layer 18 including graphics 42. In particular, graphics 42 in FIG. 2C include an image of a leaf having water droplets thereon. It can be seen that lenses/lens arrays 40 of first layer 16 are of the same/similar size, shape, contour, etc. of water droplets of graphics 42. When first layer 16 is positioned adjacent to second layer 18, first layer 16 is positioned such that the lenses/lens arrays 40 of first layer 16 are in register with the water droplet images of the graphics 42 of second layer. While FIG. 2B shows a darker background behind the first layer, first layer may be a clear layer (to allow image on substrate beneath the first layer to be observed once first layer is positioned adjacent to second layer).

While the example, above, is described as bringing a first layer 16 having lens/lens array 40 thereon into register with images of graphics 42 of second layer 18, in alternate embodiments, one may position a first layer 16 adjacent to second layer 18 (such as by applying a coating onto second layer), and thereafter embossing lens/lens array 40 in register with the graphics 42 of second layer 18. (Once first layer 16 is positioned adjacent second layer 18 on a carrier web 20, a cross section of first and second layers 16, 18 from FIGS. 2B and 2C would appear similar to the figure shown in FIG. 2A.)

Additionally, or alternatively, the label may also include images that are themselves formed via being imprinted (such as via embossing) of the first layer. In certain embodiments, the embossing of the first layer may be done in the shape, contour, etc., of the graphics (such as text, images, etc.) that are desired to appear to an observer of the label. Other embodiments may include embossing of the first layer in the shape, contour, etc., of the graphics (such as text, images, etc.) that are desired top appear to an observer of the label, coupled with the formation of at least one lens or lens array that provides further visual effect to the embossed graphics. Such a lens or lens array may be provided on the first layer, or on a separate layer of the label.

Further, the label may include a protective film, and the embossed first layer 16 may be positioned such that it lies underneath the film (i.e., toward the inside of the label 10 once associated with an article). When the embossed first layer 16 is positioned underneath the film, this can prevent abrasion of the embossed surface 12.

The processes provided by the various aspects of the present invention that create the lens array (e.g., a micro-structure lens array) of the label may result in the creation of lens elements chosen from the group of multilevel diffractive lenses, Fresnel lenses, lenticular lenses, and microlenses. As is known, a Fresnel lens is a lens having a smaller thickness by concentrically cutting a spherical or aspherical lens having a continuous lens surface (or continuous refracting surface) and structurally has sawtooth prisms disposed stepwise. The sawtooth prisms each include a “lens surface” that turns the direction of light traveling; and a “non-lens surface” that transmits light. The Fresnel lens according to the present invention is a Fresnel lens which has two or more sawtooth prisms and effectively concentrates or disperses light. Further, the lens array (e.g., a micro-structure lens array) can provide a diffraction capability that allows for various optical effects, such as holographic patterns associated with the label.

In embodiments where the lens array includes a multilevel diffractive lens, and where a three dimensional optical effect is desired, a 3D model of the image may be created using software such as Solid Works. The 3D image is then sliced and flattened to a printable height, which is then registered to printed graphics resulting in a virtual 3D image. For example, the 3D image is then sliced and flattened to a printable height of around 1.2 microns, which is then registered to printed graphics resulting in a virtual 3D image.

As described above, in at least one embodiment of the invention, the lens array (e.g., a micro-structure lens array) may be provided in the surface 12 of a coating 16 that is part of the label 10. In various embodiments, this coating may be a clear coating or, alternatively, may be a colored coating. The structures that make up the lens array may be directly printed onto/into this coating. The coating may be a varnish. One nonlimiting example of a varnish or coating layer that can be used with embodiments of the present invention is SunCure® HG (High Gloss) TL 4098 coating (commercially available under product number RCYFV0484098 from Sun Chemical, of Parsippany-Troy Hills, N.J.). Other nonlimiting examples of a varnish or coating layer that can be used with embodiments of the present invention include BTC 6678 SR, commercially available from Minus Nine of Birdsboro, Pa., and U37860G, commercially available from Nicoat of Itasca, Ill. Each of the above materials is of acrylate chemistry. In various embodiments, the material of the coating may be a UV acrylate.

In one particular embodiment, the surface that is coated is a surface of an overprint varnish of the label. And, in certain embodiments, the varnish has a refractive index in the range of 1.5 to 1.7.

Another aspect of the invention provides a method for preparing a label. The label may include a lens or lens array (e.g., a micro-structure lens array). In this aspect, the method comprises applying a coating to a film, and embossing a portion of the coating to provide a lens or lens array (e.g., a micro-structure lens array).

One embodiment of this aspect of providing a method of preparing a label may include applying a material to a substrate; and contacting a surface of the material with a master engraving to provide an embossed region on a least a portion of the surface of the material; wherein the embossed region provides at least one lens.

This embodiment may further include curing the material subsequent to the surface of the material being contacted with the master engraving. Alternatively, the material may be cured in concert with the surface of the material being contacted with the master engraving (i.e., at substantially the same time).

Further, as described, the substrate may include at least one graphic. This at least one graphic may be provided by at least one ink on a surface of the substrate. Alternatively, or additionally, the substrate layer may include an ink that provides the at least one graphic. In this embodiment, contacting of the surface of the material with a master engraving may be done in a manner that provides the embossed region in register with the at least one graphic. Alternatively or additionally, contacting of the surface of the material with a master engraving may be done in a manner that provides the embossed region in register with a portion of the at least one graphic. And, the at least one graphic of the substrate may be part of a plurality of graphics associated with the substrate, and contacting of the surface of the material with a master engraving may be done in a manner that provides the embossed region in register with one or more of the plurality of graphics, or with portions thereof.

Another embodiment of this aspect of providing a method of preparing a label may include contacting a surface of a material with a master engraving to provide an embossed region on a least a portion of the surface of the material; and applying the material including an embossed region to a substrate; wherein the embossed region provides at least one lens.

This embodiment may further include curing the material subsequent to the surface of the material being contacted with the master engraving. Alternatively, the material may be cured in concert with the surface of the material being contacted with the master engraving (i.e., at substantially the same time).

Further, as described, the substrate may include at least one graphic. This at least one graphic may be provided by at least one ink on a surface of the substrate. Alternatively, or additionally, the substrate layer may include an ink that provides the at least one graphic. In this embodiment, applying the material to the substrate may be done done in a manner to provide the embossed region in register with the at least one graphic. Alternatively or additionally, applying the material to the substrate may be done in a manner to provide the embossed region in register with a portion of the at least one graphic. And, the at least one graphic of the substrate may be part of a plurality of graphics associated with the substrate, and applying the material to the substrate may be done in a manner to provide the embossed region in register with one or more of the plurality of graphics, or with portions thereof.

Another embodiment of this aspect of providing a method of preparing a label may include contacting a surface of a material with a master engraving to provide an embossed region on a least a portion of the surface of the material, as the material is being applied to a substrate; wherein the embossed region provides at least one lens.

This embodiment may further include curing the material subsequent to the surface of the material being contacted with the master engraving. Alternatively, the material may be cured in concert with the surface of the material being contacted with the master engraving (i.e., at substantially the same time).

Further, as described, the substrate may include at least one graphic. This at least one graphic may be provided by at least one ink on a surface of the substrate. Alternatively, or additionally, the substrate layer may include an ink that provides the at least one graphic. In this embodiment, contacting of the surface of the material with a master engraving may be done in a manner that provides the embossed region in register with the at least one graphic. Alternatively or additionally, contacting of the surface of the material with a master engraving may be done in a manner that provides the embossed region in register with a portion of the at least one graphic. And, the at least one graphic of the substrate may be part of a plurality of graphics associated with the substrate, and contacting of the surface of the material with a master engraving may be done in a manner that provides the embossed region in register with one or more of the plurality of graphics, or with portions thereof.

By providing such a method, this aspect of the present invention overcomes the drawbacks described above with present methods of preparing labels. For example, as described in the Background, current methods, such as the CAST AND CURE™ method, do not provide high quality optical effects for images (or images). This is because the embossed film used to provide the emboss to the CAST AND CURE™ coating is a secondary film. As described, a master engraving is first used to make an embossed film. And that second embossed film is then used to make the emboss that is on the coating of the final label (or other embossed material). Thus, the emboss on the final material is not going to be as sharp as that one the original film provided by the original master engraving. Further, once the final embossed product is prepared, the secondary embossed CAST AND CURE™ film has to be removed and discarded.

The present method, however, prepares the embossing of the portions of the material of the label that will provide a lens or lens array directly from the master engraving itself. This results in higher quality emboss in the present labels than in materials prepared from the prior methods. And this, in turn, results in higher quality optical effects, and thus higher quality images. And, this is accomplished in a method that—at the same time—eliminates the prior art's use of an extra material (the secondary embossed film) that has to be removed and discarded once the emboss is complete. Further, by having a method that allows the emboss to prepared directly from the master engraving to the final product, the present invention allows for all of the steps to prepare the final label to occur in a single in-line process—thereby eliminating the need to obtain a pre-manufactured substrate.

In one exemplary embodiment, the method for preparing a label in accordance with the principles described herein first includes applying a coating to a film. The coating may be clear or colored, and may be a varnish. The film may be opaque or clear. One nonlimiting example of such a film is a polypropylene film, for example a biaxial oriented polypropylene film, such as that commercially available as TE40 polypropylene film from Amtopp (of the Interplast Group, of Livingston, N.J.). However, it should be recognized that there is no limit to the type of material that can be used as the film. For example, paper, foil, PETG, styrene, polyethylene, polypropylene, acetate, and/or other materials (including anything used in the label and flexible packaging industry) can be used as the film described herein. And, as described above, one nonlimiting example of an imprintable varnish or coating layer is SunCure® HG (High Gloss) TL 4098 coating (commercially available under product number RCYFV0484098 from Sun Chemical, of Parsippany-Troy Hills, N.J.). The application of the coating to the film may be accomplished via a printing process chosen from the group of flexo printing, gravure printing, ink jet printing, or any conventional printing method. In certain embodiments, the coating (e.g., varnish) may be applied to have a thickness of about 50 nm to 150 μm. The coating may be applied as a continuous coating, or it may be applied as a pattern.

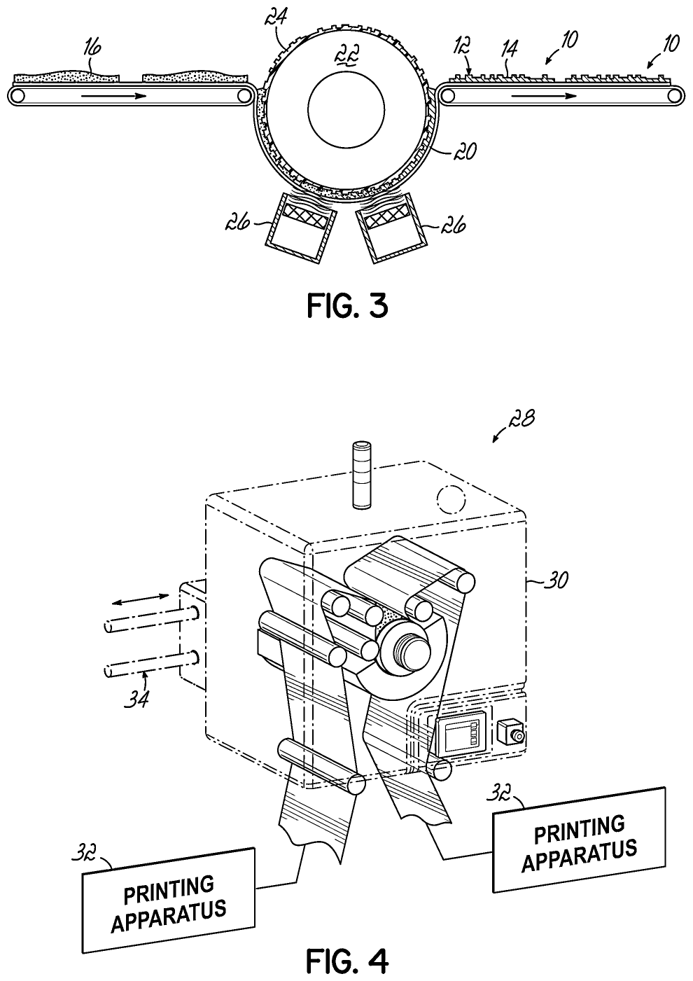

In one embodiment of the method of preparing the label, after applying the coating to the film, a portion of the coating is then embossed to provide the lens or lens array (e.g., a micro-structure lens array). For example, in embodiments of the invention, embossing provides contours in the coating that create, or operate as, a lens or lens array. As the embossed structures can be of size ranging in the nanometers to micrometers, it can be referred to as a micro-structure lens array. (As described above, when “micro-structure lens array” is used herein, that should be taken to encompass not only formed lens structures in the nanometer or micrometer range, but also in the millimeter range.) In one embodiment, an imprint lithography process may be used to provide embossed images in the coating. The scale of the imprinting may range from the extremely small scale (nanometer sized features) to larger (micrometer or even millimeter scale sized features). (Thus, the imprint lithography process may be a nanoimprint lithography process.) To accomplish this, and referring now to FIG. 3, the film having the coating 16 thereon is positioned relative to (e.g., around) a cylinder 22 that has been engraved with an embossing region 24 thereon—such as by being nipped around a cylinder 22 that has been engraved (e.g., via a diamond cut engraving process or a laser engraving process) with an embossing region 24 (which will form the embossed region on at least a portion 14 of the coating 16 of the label 10 to provide the lens array and/or images associated with the label).

This embodiment of the method may then further include curing the coating in order to fix the embossing thereon or therein. Thus, in one embodiment, the coating 16 may be cured while the coating 16 is in contact with the engraved embossing region 24 on the engraved cylinder 22. In one example of an embodiment, the coating 16 may be cured via a UV-curing process (such as by using a curing apparatus 26, such as a UV powered lamp). In such an embodiment, the base of the cylinder, a UV powered lamp cures the varnish while in contact with the embossed region of the engraved cylinder. Thus, one method of curing is with UV light. Another method is with LED powered UV light. Thus, rather than using a custom designed coating (i.e., a pre-manufactured film as described in the Background), aspects of the present invention use an existing coating (varnish) that is present in the manufacture of the labels. This eliminates extra materials and extra steps of current methods described above, thereby simplifying the process and reducing its cost. Another option is to utilize a clear cylinder in which the UV lamp is positioned in the cylinder and cures through the cylinder where the coating is in contact with the outer surface of the cylinder. This allows one to utilize opaque materials which could not be cured through with the external mounted UV lamp.

The film may then be subsequently printed with remaining graphics in register with the embossed structure. This subsequent printing may be accomplished via any known printing process.

Further, it will be recognized by those of ordinary skill in the art that—while the above embodiment describes first embossing images in the varnish and then printing remaining graphics—this order is not essential. In alternate embodiments, the graphics may be printed first, followed by embossing images.

Further, the label 10 may be one of a plurality of labels disposed on a surface of a carrier sheet 20 (a web for labels) as it moves through apparatus for printing graphics on the labels. Thus, the labels 10 on the carrier sheet 20 (web) may each have an embossing process applied thereto to create a lens or lens array (e.g., a micro-structure lens array). And this can be done in line with additional graphics (designs, logos, text, other indicia, etc.) being printed on the labels.

As described above, another aspect of the present invention provides a system for preparing a label having a lens array (e.g., a micro-structure lens array). Referring to FIG. 4, the system 28 may include an embossing apparatus 30 associated with a printing apparatus 32. Such apparatus may include an embossing station that can be mounted on any printing press. This allows the embossing of images to occur in line with the further printing of additional graphics to a web of labels.

Further, in certain embodiments, the embossing station can be mounted on a rail system 34 which allows it to be moved to any location on the press. Accordingly, the embossed region can be printed at any time during the printing process. Further, because the apparatus (and ability to produce embossed regions—such as a printed lens or lens array) is in line on the printing press, the technology can be combined with all forms of labels (e.g., pressure sensitive, heat transfer, shrink sleeve, etc.), packaging, and printed media.

The imaging technology described herein may be combined with any conventional printing processes, including but not limited to UV flexo, rotary screen, lithography, digital, gravure, letterpress, and any combination of conventional printing.

By creating the image during the printing process, labels can be produced that enhance security and offer an anti-counterfeiting benefit. By creating the image in line, the likelihood of theft or duplication of the images is reduced. The potential size of the images that can be produced are in the 100 nm range (or even smaller) making it extremely difficult to detect except with very high magnification. This means that microscopic features may be introduced to the printed image as a “signature” element.

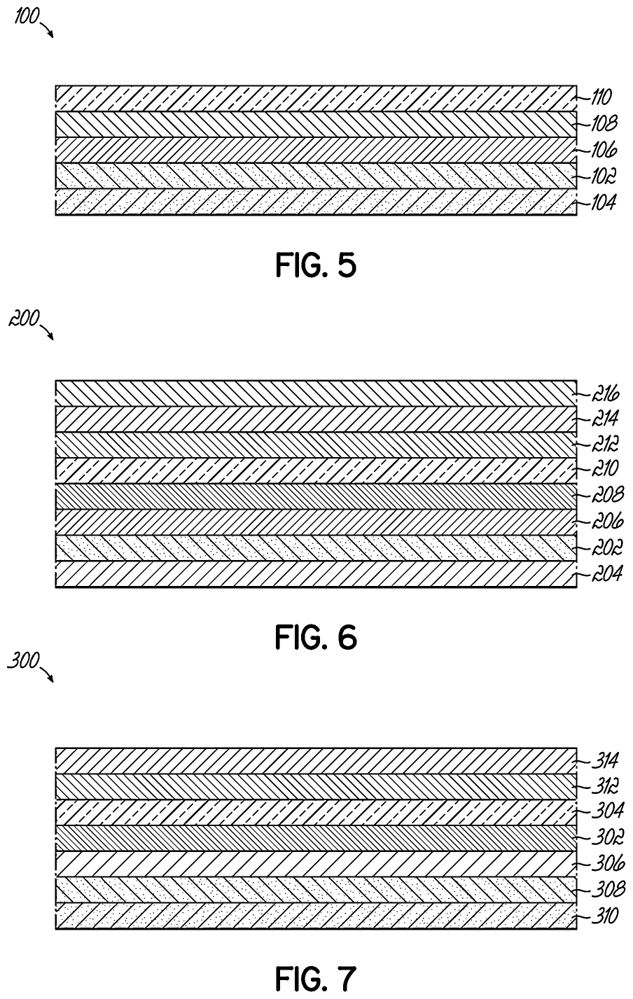

Referring Now to FIG. 5, another embodiment of a label 100 in accordance with principles of the present invention is shown. In this embodiment, an adhesive material 102 is positioned on one surface of a pressure sensitive material 104. A layer 106 including graphics is then positioned adjacent to the adhesive 102 such that the adhesive is between the layer 106 including graphics and the pressure sensitive material 104. A layer 108 including a micro-lens array (which is an embossed layer 108, with the embossing forming a multilevel diffractive lens) is then positioned such that the graphics layer 106 is between the embossed layer 108 and the adhesive 102. And a film 110 (e.g. a transparent film) is positioned such that the embossed layer 108 is between the film 110 and the graphics layer 106.

In a method of preparing the embodiment of the label shown in FIG. 5, a coating (such as a coating having a multilevel diffractive lens embossed thereon) may be applied to a surface of a film 110 (e.g. a transparent film). The coating thus provides the embossed layer 108. The embossing may occur prior to, or following application of the coating to the film. The film 110 and embossed coating 108 may then overlie a layer 106 of graphics (provided by inks), wherein the printed graphics layer overlies an adhesive layer 102. This construction of film, embossed coating, graphics, and adhesive may then be positioned on a pressure sensitive material 104, such that the adhesive layer is adjacent to the pressure sensitive material (and positioned between the pressure sensitive material and the graphics. The pressure sensitive material layer shown in FIG. 5 can be representative of a single layer material, or can be seen to represent a stock pressure sensitive material that may itself include multiple layers.

Still referring to the embodiment of FIG. 5, the label 100 includes a film layer 110 as the top layer in the illustration of the figure. More specifically, this layer may be a transparent film layer, such as would be provided by a clear polypropylene film. In one particular embodiment, the film layer may be a 40 micron clear polypropylene film (AmTopp). Further, the label 100 includes an embossed layer 108 as the layer immediately adjacent the lower surface of the top layer in the embodiment of FIG. 5. More specifically, this embossed layer may be an embossed varnish. And in one particular embodiment, the embossed layer may be a nano imprint lithography embossed 4098 clear Sun varnish.

Referring now to FIG. 6, an alternate embodiment of a label 200 in accordance with the principles of the present invention is shown. The embodiment of FIG. 6 includes the general construction shown in FIG. 5: In other words, the embodiment of FIG. 6 includes an adhesive material 202 positioned on one surface of a pressure sensitive material 204. A first layer 206 including graphics is then positioned adjacent to the adhesive 202 such that the adhesive 202 is between the first layer 206 including graphics and the pressure sensitive material 204. A layer 208 including a micro-lens array (which is an embossed layer 208, with the embossing forming a multilevel diffractive lens) is then positioned such that the first graphics layer 206 is between the embossed layer 208 and the adhesive 202. And a film 210 (e.g. a transparent film) is positioned such that the embossed layer 208 is between the film 210 and the first graphics layer 206.

However, the embodiment of FIG. 6 includes additional layers over and above that shown in the embodiment of FIG. 5. To that end, in addition to the layers referenced above, the embodiment of FIG. 6 also includes a second graphics layer 212 positioned on the opposite side of the film layer 210 (such that the film 210 is positioned between the embossed layer 208 and the second graphics layer 212. A first varnish layer 214 is then positioned such that the second graphics layer 212 is between the film 210 and the first varnish layer 214. This varnish layer 214 may include a gloss varnish. And a second varnish layer 216 is then positioned such that the first varnish layer 214 is positioned between the second graphics layer 212 and the second varnish layer 216. The second varnish layer 216 may include a matte varnish.

Referring now to FIG. 7, an alternate embodiment of a label 300 in accordance with the principles of the present invention is shown. The label of this embodiment includes a coating 302 with a lens array (such as a multilevel diffractive lens) embossed therein or thereon (an embossed coating 302) positioned adjacent to a surface of a film 304 (such as a transparent film). A reflective coating 306 is then positioned adjacent the embossed coating 302 such that the embossed coating 302 is positioned between the film 304 and the reflective coating 306. An adhesive 308 is then placed on the opposite side of the reflective coating 306 from the embossed coating 302. And then a liner 310 is placed on a side of the adhesive 308 opposite the reflective coating 306. A graphics layer 312 (to provide indicia via inks, for example) is positioned adjacent a side of the film 304 that is opposite the embossed coating 302. And then a gloss varnish 314 is positioned on the opposite side of the graphics layer 312 from the film 304.

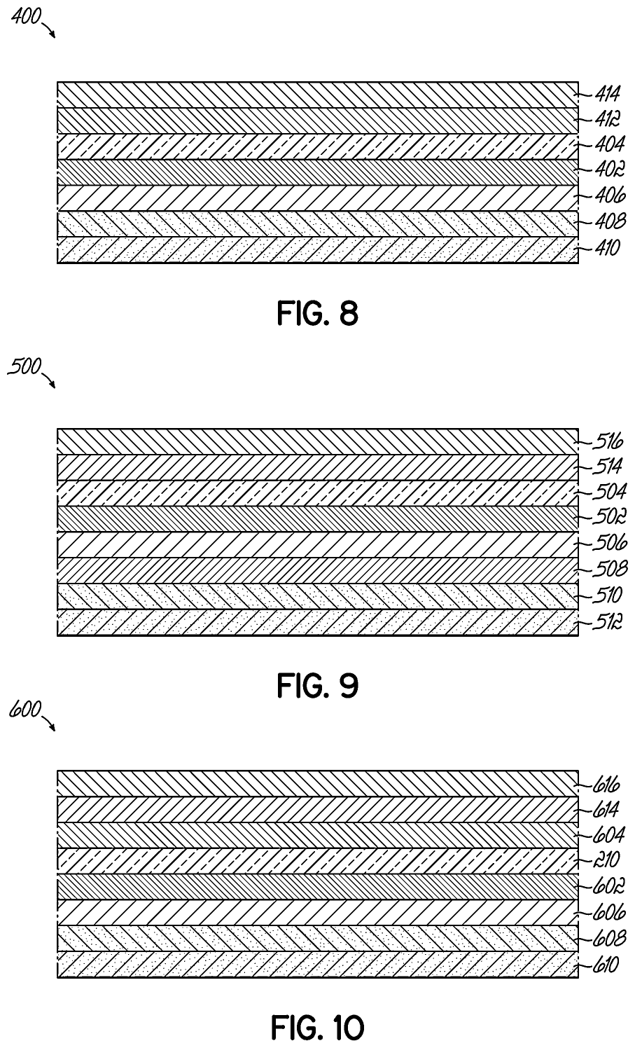

Referring now to FIG. 8, an alternate embodiment of a label 400 in accordance with the principles of the present invention is shown. This embodiment is similar to the embodiment of FIG. 7, except this embodiment includes a matte varnish, rather than a gloss varnish. Thus, the label of this embodiment includes a coating 402 with a lens array (such as a multilevel diffractive lens) embossed therein or thereon (an embossed coating 402) positioned adjacent to a surface of a film 404 (such as a transparent film). A reflective coating 406 is then positioned adjacent the embossed coating 402 such that the embossed coating 402 is positioned between the film 404 and the reflective coating 406. An adhesive 408 is then placed on the opposite side of the reflective coating 406 from the embossed coating 402. And then a liner 410 is placed on a side of the adhesive 408 opposite the reflective coating 406. A graphics layer 412 (to provide indicia via inks, for example) is positioned adjacent a side of the film 404 that is opposite the embossed coating 402. And then a matte varnish 414 is positioned on the opposite side of the graphics layer 412 from the film 404.

Referring now to FIG. 9, an alternate embodiment of a label 500 in accordance with the principles of the present invention is shown. The label of this embodiment includes a coating 502 with a lens array (such as a multilevel diffractive lens) embossed therein or thereon (an embossed coating 502) positioned adjacent to a surface of a film 504 (such as a transparent film). A reflective coating 506 is then positioned adjacent the embossed coating 502 such that the embossed coating 502 is positioned between the film 504 and the reflective coating 506. A graphics layer 508 (e.g., including inks forming indicia) is then placed on a side of the reflective coating 506 opposite the embossed coating 502. An adhesive 510 is then placed on the opposite side of the of the graphics layer 508 from the reflective coating 506. And then a liner 512 is placed on a side of the adhesive 510 opposite the graphics layer 508. The label 500 may then also include a first varnish layer 514 and a second varnish layer 516. In the illustrated embodiment, the first varnish layer 514 may be positioned adjacent the film 504 opposite from the embossed coating 502. The first varnish layer 514 may include a gloss varnish. In the illustrated embodiment, the second varnish layer 516 may be positioned adjacent the first varnish layer 514 opposite from the film 504. The second varnish layer 516 may include a matte varnish.

Referring now to FIG. 10, an alternate embodiment of a label 600 in accordance with the principles of the present invention is shown. The label of this embodiment is similar to that shown in FIG. 9, except for the positioning of the first graphics layer. The label of this embodiment includes a coating 602 with a lens array (such as a multilevel diffractive lens) embossed therein or thereon (an embossed coating 602) positioned adjacent to a surface of a film 604 (such as a transparent film). A reflective coating 606 is then positioned adjacent the embossed coating 602 such that the embossed coating 602 is positioned between the film 604 and the reflective coating 606. An adhesive layer 608 is then placed on a side of the reflective coating 606 opposite the embossed coating 602. And then a liner 610 is placed on the opposite side of the of the adhesive layer 608 from the reflective coating 606. The label 600 then also includes a graphics layer 612 positioned adjacent a side of the film 604 opposite the embossed coating 602. The label may then also include a first varnish layer 614 and a second varnish layer 616. In the illustrated embodiment, the first varnish layer 614 may be positioned adjacent the graphics layer 612 opposite from the film 604. The first varnish layer 614 may include a gloss varnish. In the illustrated embodiment, the second varnish layer 616 may be positioned adjacent the first varnish layer 614 opposite from the graphics layer 612. The second varnish layer 616 may include a matte varnish.

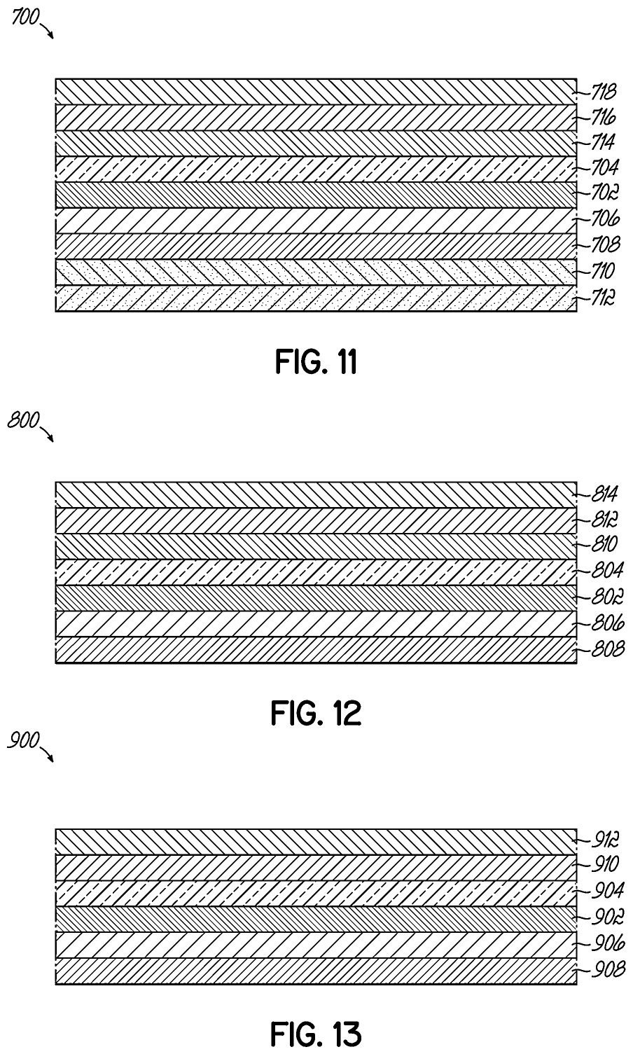

Referring now to FIG. 11, an alternate embodiment of a label 700 in accordance with the principles of the present invention is shown. The label of this embodiment is similar to that shown in FIGS. 9 and 10, except it includes two graphics layers. The label of this embodiment includes a coating 702 with a lens array (such as a multilevel diffractive lens) embossed therein or thereon (an embossed coating 702) positioned adjacent to a surface of a film 704 (such as a transparent film). A reflective coating 706 is then positioned adjacent the embossed coating 702 such that the embossed coating is positioned between the film 704 and the reflective coating 706. A first graphics layer 708 (e.g., including inks forming indicia) is then placed on a side of the reflective coating 706 opposite the embossed coating 702. An adhesive 710 is then placed on the opposite side of the of the first graphics layer 708 from the reflective coating 706. And then a liner 712 is placed on a side of the adhesive 710 opposite the first graphics layer 708. The label 700 then also includes a second graphics layer 714 positioned adjacent a side of the film 704 opposite the embossed coating 702. The label may then also include a first varnish layer 716 and a second varnish layer 718. In the illustrated embodiment, the first varnish layer 716 may be positioned adjacent the second graphics layer 714 opposite from the film 704. The first varnish layer 716 may include a gloss varnish. In the illustrated embodiment, the second varnish layer 718 may be positioned adjacent the first varnish layer 716 opposite from the second graphics layer 714. The second varnish layer 718 may include a matte varnish.

Referring now to FIG. 12, an alternate embodiment of a label 800 in accordance with the principles of the present invention is shown. The label of this embodiment includes a coating 802 with a lens array (such as a multilevel diffractive lens) embossed therein or thereon (an embossed coating 802) positioned adjacent to a surface of a film 804 (such as a transparent film). A reflective coating 806 is then positioned adjacent the embossed coating 802 such that the embossed coating 802 is positioned between the film 804 and the reflective coating 806. A first graphics layer 808 (e.g., including inks forming indicia) is then placed on a side of the reflective coating 806 opposite the embossed coating 802. The label 800 then also includes a second graphics layer 810 positioned adjacent a side of the film 804 opposite the embossed coating 802. The label may then also include a first varnish layer 812 and a second varnish layer 814. In the illustrated embodiment, the first varnish layer 812 may be positioned adjacent the second graphics layer 810 opposite from the film 804. The first varnish layer 812 may include a gloss varnish. In the illustrated embodiment, the second varnish layer 814 may be positioned adjacent the first varnish layer 812 opposite from the second graphics layer 810. The second varnish layer 814 may include a matte varnish.

Referring now to FIG. 13, an alternate embodiment of a label 900 in accordance with the principles of the present invention is shown. The label of this embodiment includes a coating 902 with a lens array (such as a multilevel diffractive lens) embossed therein or thereon (an embossed coating 902) positioned adjacent to a surface of a film 904 (such as a transparent film). A reflective coating 906 is then positioned adjacent the embossed coating 902 such that the embossed coating 902 is positioned between the film 904 and the reflective coating 906. A graphics layer 908 (e.g., including inks forming indicia) is then placed on a side of the reflective coating 906 opposite the embossed coating 902. The label may then also include a first varnish layer 910 and a second varnish layer 912. In the illustrated embodiment, the first varnish layer 910 may be positioned adjacent the film 904 opposite from the embossed coating 902. The first varnish layer 910 may include a gloss varnish. In the illustrated embodiment, the second varnish layer 912 may be positioned adjacent the first varnish layer 910 opposite from the film 904. The second varnish layer 912 may include a matte varnish.

Various specific materials to use for each of the layers described in all of these embodiments (e.g., films, inks, coatings, etc.) may include all those described elsewhere in this application with respect to specific embodiments.

### EXAMPLE

Labels (in accordance with principles of the present invention) were prepared, and the labels (and images thereon provided by the graphics layer(s) and enhanced by the embossed layer) were then tested. In particular, three tests were performed to see how the embossed coating withstood basic testing for existing label technologies.

Materials

Face stocks used in tested labels were: (1) TE-40B, which is a 40 micron clear Polypropylene film supplied by AmTopp (of the Inteplast Group, of Livingston, N.J.), and (2) a Clear 48-gauge 453 PET film supplied by DuPont Tlijin Films of Hopewell, Va.

Embossable coatings tested included Sun Chemical SunCure 4098 Varnish. This is a high gloss, non-yellowing, and chemical resistant UV curable varnish used to make the multilevel diffractive lens appearance on the face stocks.

Reflective coatings tested included (1) NOVAMET mirror Silver 2155 (a solvent gravure ink made of vacuum metalized aluminum flakes for the decoration of labels); and (2) NOVAPEARL White 2069 [a solvent gravure ink based on white pearl (bismuth oxychloride) flakes for decoration of labels].

Methods

600 Tape Test: Test was conducted with ½ inch 600 tape and a weighted roller. The tape was applied to the sample to evaluate all varnishes and inks. The tape was rolled 5 times with the weighted roller and allowed to dwell for 15 seconds. Upon removal from sample, tape was inspected for any ink/varnish transfer.

Sutherland Rub Test: Test was conducted with chipboard for 100 cycles using a 4-lb weight. Samples were inspected for defects upon completion of the test.

Soapy Water Test: Samples were applied to HDPE bottles. Bottles were squeezed panel to panel twice and then soaked in soap concentrated water for 2 minutes. Then bottles were moved to room temperature water, squeezed twice, and left to soak for 2 minutes. Samples underwent 11 cycles. Samples were evaluated for ink/varnish removal.

### DISCUSSION

The three tests listed above were done to see how the embossed coating withstood basic testing for existing label technologies. The multilevel diffractive lens passed the testing listed above. There were no issues with the tape test or Sutherland rub testing. When doing the soapy water testing, the embossed image would disappear when the label was wet. Once dry the image returned. However, when the embossed image was on the inside and did not touch the water the image remained visible for the duration of the test. Numerous samples created using different graphic layout and application techniques. Prototyped samples were made to determine the best graphic layout that will later be recreated on press. Matched overall finished design by color and appearance to the current product on the market. Did multiple variations of drawdowns with the reflective coatings to see which sample of coating yielded the best look for the technology.

The embodiments of the present invention recited herein are intended to be merely exemplary and those skilled in the art will be able to make numerous variations and modifications to it without departing from the spirit of the present invention. Notwithstanding the above, certain variations and modifications, while producing less than optimal results, may still produce satisfactory results. All such variations and modifications are intended to be within the scope of the present invention as defined by the claims appended hereto.

What is claimed is:

1. A method of preparing a label, the method comprising:
applying a material to a substrate; and
contacting a surface of the material with a master engraving to provide an embossed region on a least a portion of the surface of the material;
wherein the embossed region provides at least one lens.

2. The method of claim 1, wherein the material is a coating.

3. The method of claim 2, wherein the coating includes a varnish.

4. The method of claim 2, wherein the coating has a thickness in the range of 50 nm to 150 μm.

5. The method of claim 1, further comprising curing the material subsequent to the surface of the material being contacted with the master engraving.

6. The method of claim 1, further comprising curing the material in concert with the surface of the material being contacted with the master engraving.

7. The method of claim 2, wherein applying the coating to the substrate is accomplished via a printing process chosen from the group of flexo printing, gravure printing, and ink jet printing.

8. The method of claim 1, wherein the substrate includes at least one graphic.

9. The method of claim 8, wherein the at least one graphic is provided by at least one ink on a surface of the substrate.

10. The method of claim 8, wherein the substrate layer comprises an ink that provides the at least one graphic.

11. The method of claim 8, wherein the contacting of the surface of the material with a master engraving provides the embossed region in register with the at least one graphic.

12. The method of claim 8, wherein the contacting of the surface of the material with a master engraving provides the embossed region in register with a portion of the at least one graphic.

13. The method of claim 8, wherein the at least one graphic of the substrate is part of a plurality of graphics associated with the substrate, and wherein the contacting of the surface of the material with a master engraving provides the embossed region in register with one or more of the plurality of graphics, or with portions thereof.

14. The method of claim 1, wherein the substrate comprises a film.

15. The method of claim 14, wherein the film includes polypropylene.

16. The method of claim 15, wherein the film is a biaxially-oriented polypropylene film.

17. A method of preparing a label, the method comprising:
contacting a surface of a material with a master engraving to provide an embossed region on a least a portion of the surface of the material; and
applying the material including an embossed region to a substrate;
wherein the embossed region provides at least one lens.

18. The method of claim 17, wherein the material is a coating.

19. The method of claim 18, wherein the coating includes a varnish.

20. The method of claim 18, wherein the coating has a thickness in the range of 50 nm to 150 μm.

21. The method of claim 17, further comprising curing the material subsequent to the surface of the material being contacted with the master engraving.

22. The method of claim 17, further comprising curing the material in concert with the surface of the material being contacted with the master engraving.

23. The method of claim 18, wherein applying the coating to the substrate is accomplished via a printing process chosen from the group of flexo printing, gravure printing, and ink jet printing.

24. The method of claim 17, wherein the substrate includes at least one graphic.

25. The method of claim 24, wherein the at least one graphic is provided by at least one ink on a surface of the substrate.

26. The method of claim 24, wherein the substrate layer comprises an ink that provides the at least one graphic.

27. The method of claim 24, wherein applying the material to the substrate is done in a manner to provide the embossed region in register with the at least one graphic.

28. The method of claim 24, wherein applying the material to the substrate is done in a manner to provide the embossed region in register with a portion of the at least one graphic.

29. The method of claim 24, wherein the at least one graphic of the substrate is part of a plurality of graphics associated with the substrate, and wherein applying the material to the substrate is done in a manner to provide the embossed region in register with one or more of the plurality of graphics, or with portions thereof.

30. The method of claim 17, wherein the substrate comprises a film.

31. The method of claim 30, wherein the film includes polypropylene.

32. The method of claim 31, wherein the film is a biaxially-oriented polypropylene film.

33. A method of preparing a label, the method comprising:
contacting a surface of a material with a master engraving to provide an embossed region on a least a portion of the surface of the material, as the material is being applied to a substrate;
wherein the embossed region provides at least one lens.

34. The method of claim 33, wherein the material is a coating.

35. The method of claim 33, further comprising curing the material subsequent to the surface of the material being contacted with the master engraving.

36. The method of claim 33, further comprising curing the material in concert with the surface of the material being contacted with the master engraving.

37. The method of claim 33, wherein the substrate includes at least one graphic.

38. The method of claim 37, wherein the contacting of the surface of the material with a master engraving provides the embossed region in register with the at least one graphic.

39. The method of claim 37, wherein the contacting of the surface of the material with a master engraving provides the embossed region in register with a portion of the at least one graphic.

40. The method of claim 37, wherein the at least one graphic of the substrate is part of a plurality of graphics associated with the substrate, and wherein the contacting of the surface of the material with a master engraving provides the embossed region in register with one or more of the plurality of graphics, or with portions thereof.
